(19) United States
(12) Patent Application Publication
(10) Pub. No.: US 2006/0199298 A1
(43) Pub. Date: Sep. 7, 2006

(54) Creation of hermetically sealed dielectrically isolating trenches

(76) Inventor: Karlheinz Freywald, Erfurt (DE)

Correspondence Address: DUANE MORRIS, LLP;IP DEPARTMENT, 30 SOUTH 17TH STREET, PHILADELPHIA, PA, 19103-4196, US

(21) Appl. No.: 10/537,212

(22) PCT Filed: Dec. 5, 2003
(86) PCT No.: PCT/DE03/04014

§ 371 Date: Apr. 3, 2006

(30) Foreign Application Priority Data
Dec. 5, 2002 (DE) 102 57 098.1

(51) Int. Cl. H01L 21/00; H01L 23/02

(52) U.S. Cl. 438/106; 257/678

(57) ABSTRACT

The invention relates to a method and an assembly for forming structures that are dielectrically insulated from each other by means of filled hermetically sealed isolation trenches for the formation of mechanical-electrical sensor structures, which require for their functioning a hermetically sealed cavity, in which are located the moveable sensor elements.

### BACKGROUND OF THE INVENTION

The invention relates to a method and an assembly for forming structures that are dielectrically insulated from each other by means of filled hermetically sealed isolation trenches for the formation of mechanical-electrical sensor structures, which require for their functioning a hermetically sealed cavity, in which are located the moveable sensor elements.

### BRIEF SUMMARY OF THE INVENTION

Filled trench structures are used, for instance, for the dielectric insulation of high voltage elements, cf. DE-A 198 28 669, or for the dielectric and capacitance-reduced insulation in integrated HF elements and for the formation of insulated portions for electromechanic structures, cf. DE-C 100 29 012. Filled trench structures are preferably used for SOI wafers, as well as for single-crystalline semiconductor wafers for the dielectric peripheral insulation of source/drain portions in CMOS circuits, cf. DE-A 197 06 789.

The electrical, mechanical and thermal requirements for such trench structures and the filling thereof are different depending on the technology and the preceding technology steps (for instance, integration in a CMOS technology). For this reason, also different materials and methods are used for the filling of such electrically insulating trench structures. The materials used are preferably silicon dioxide, silicon nitride, polysilicon or organic materials, such as polyamide. Generally, priority is given to a void free or void reduced filling so as to avoid any gas enclosures. The methodological conditions therefore may, however, match those required for highly integrated circuit technology and require high efforts in case the conditions have to be correspondingly adapted.

In most situations, the shape of the trenches is selected so as to exhibit vertical walls or so as to exhibit a v-shaped tapered portion in order to facilitate a void free filing, cf. JP-A 2002 100 672, “Forming Method of Isolation Trench.” The advances in this field also refer to mechanical electrical structures as a part of the complex semiconductor manufacturing process (for instance, CMOS technology) and, thus, require the realization of hermetically sealed cavities for the functioning of these mechanically moveable structures, cf. DE-A 100 17 976. During the filling of the trenches, channel-shaped cavities may readily be formed in the interior of the trench caused by a rapid growing together of the fill material at the upper side of the trench, starting from the upper trench edges. The cavities or voids may tunnel through the boundary of the sensor cavity that should hermetically be sealed, thereby resulting in a failure of the device owing to damage of the actual sensor element.

For sophisticated requirements with respect to the trench geometry, when vertical sidewalls or v-shaped cross sections may not be realized and under-cut edges are admissible, new approaches have to be found.

It is the object of the invention to overcome the deficiencies described above that occur during the filling of isolation trenches having a standard cross sectional shape, which may be associated with void or cavity channels that laterally extend and that are produced during the filling process, in order to insure the hermetical sealing of the cavity for the mechanical electrical structures in combination with the hermetically sealed wafer bonding. Moreover, a simple and cost efficient method is to be provided, which insures a hermetical sealing of possible void channels, which may form in the lateral direction during the filling of isolation trenches. Wafers processed in such a manner should be able to be subjected to a further standard CMOS processing.

### BRIEF SUMMARY OF THE SEVERAL VIEWS OF THE DRAWINGS

FIG. 1 is a top-down view of a slight channel broadening introduced into a trench oriented lengthways horizontally, the component parts being a trench region to be filled (1), a light trench broadening (2), and a conical transition portion (3).

FIG. 2 represents a schematic illustration of a slight broadening introduced into a trench, wherein the trench regions having the normal width are already closed towards the trench top. A layer deposition only occurs in the slightly broadened channel region. The center illustration is a top-down view of the broadening oriented lengthways vertically. Cross-sectional planes of the center illustration are denoted therein (A-A, B-B) and depicted to the left and to the right of the center illustration respectively. The component parts of the illustrations are the trench region to be filled (1), the slight trench broadening (2), sidewalls of the slight trench broadening (4), all remaining voids in the area of the normal trench region (5), material for filling the trench (9), the silicon environment (10), and arrows between the sidewalls indicating direction of the layer deposition.

FIG. 3 depicts the trench filling and the trench broadening and the closing of parasitic remaining voids. The left illustration is a top-down view of the broadening oriented lengthways vertically. A cross-sectional plane of the left illustration (C-C) is denoted therein and depicted to the right. The component parts of the illustrations are the trench region to be filled (1), the slight trench broadening (2), conical transition portion (3), sidewalls of the slight trench broadening (4), small remaining voids in the area of the trench region (1) having the normal width (5), position of the lateral filling (6), material for filling the trench (9), the silicon environment (10), and arrows between the sidewalls indicating direction of the layer deposition.

FIG. 4 illustrates the result of the trench filling with hermetical sealing of the parasitic remaining voids in the trench region by means of various trench cross sections at different positions of the total trench. The top illustration is a top-down view of the broadening oriented lengthways vertically. Cross-sectional planes of the center illustration are denoted therein (D-D, E-E, F-F) and depicted below the center illustration from left to right respectively. The component parts of the illustrations are the trench region to be filled (1), the slight trench broadening (2), conical transition portion (3), sidewalls of the slight trench broadening (4), small remaining voids in the area of the trench region (1) having the normal width (5), position of the lateral filling (6), position of the hermetic sealing in the area of the conical transition zone (7), somewhat larger remaining void in the area of the slight trench broadening (8), material for filling the trench (9), the silicon environment (10), and arrows between the sidewalls indicating direction of the layer deposition.

### DETAILED DESCRIPTION OF THE INVENTION

The invention relates to a method and an assembly for forming structures that are dielectrically insulated from each other by means of filled hermetically sealed isolation trenches for the formation of mechanical-electrical sensor structures, which require for their functioning a hermetically sealed cavity, in which are located the moveable sensor elements.

The conventional isolation trenches for the dielectric insulation of different electronic circuit portions do not automatically meet the requirements for the formation of microelectro-mechanical systems (MEMS), in which the formation of the cavities for the mechanically moveable sensor elements is also required across circuitries or circuit portion isolated from each other by trenches.

Filled trench structures are used, for instance, for the dielectric insulation of high voltage elements, cf. DE-A 198 28 669, or for the dielectric and capacitance-reduced insulation in integrated HF elements and for the formation of insulated portions for electromechanic structures, cf. DE-C 100 29 012. Filled trench structures are preferably used for SOI wafers, as well as for single-crystalline semiconductor wafers for the dielectric peripheral insulation of source/drain portions in CMOS circuits, cf. DE-A 197 06 789.

The electrical, mechanical and thermal requirements for such trench structures and the filling thereof are different depending on the technology and the preceding technology steps (for instance, integration in a CMOS technology). For this reason, also different materials and methods are used for the filling of such electrically insulating trench structures. The materials used are preferably silicon dioxide, silicon nitride, polysilicon or organic materials, such as polyamide. Generally, priority is given to a void free or void reduced filling so as to avoid any gas enclosures. The methodological conditions therefore may, however, match those required for highly integrated circuit technology and require high efforts in case the conditions have to be correspondingly adapted.

In most situations, the shape of the trenches is selected so as to exhibit vertical walls or so as to exhibit a v-shaped tapered portion in order to facilitate a void free filing, cf. JP-A 2002 100 672, “Forming Method of Isolation Trench.” The advances in this field also refer to mechanical electrical structures as a part of the complex semiconductor manufacturing process (for instance, CMOS technology) and, thus, require the realization of hermetically sealed cavities for the functioning of these mechanically moveable structures, cf. DE-A 100 17 976. During the filling of the trenches, channel-shaped cavities may readily be formed in the interior of the trench caused by a rapid growing together of the fill material at the upper side of the trench, starting from the upper trench edges. The cavities or voids may tunnel through the boundary of the sensor cavity that should hermetically be sealed, thereby resulting in a failure of the device owing to damage of the actual sensor element.

For sophisticated requirements with respect to the trench geometry, when vertical sidewalls or v-shaped cross sections may not be realized and under-cut edges are admissible, new approaches have to be found.

It is the object of the invention to overcome the deficiencies described above that occur during the filling of isolation trenches having a standard cross sectional shape, which may be associated with void or cavity channels that laterally extend and that are produced during the filling process, in order to insure the hermetical sealing of the cavity for the mechanical electrical structures in combination with the hermetically sealed wafer bonding. Moreover, a simple and cost efficient method is to be provided, which insures a hermetical sealing of possible void channels, which may form in the lateral direction during the filling of isolation trenches. Wafers processed in such a manner should be able to be subjected to a further standard CMOS processing.

The object is solved in accordance with the present invention in that, at least one defined position in the trench in a short portion (section), the trench is broadened or enlarged with a small amount (sealing point or position), and in that a deposition technique (low pressure deposition) is used for the deposition of the film material for sealing the trench, wherein the method is performed nearly at vacuum. The result of this is a trench geometry having at least two narrow sections and a broader intermediate section connecting these two narrow sections. The sealing positions or points may be replicated several times, depending on the requirements.

The principle of the sealing is based on a three-dimensional filling process in the vicinity of the respective sealing point. The locations of the broadened trench remain unfilled for a prolonged time period during the deposition of the layer for filling the trench compared to the immediately neighboring trench portions having the standard width.

When the standard trench is closing during the fill process and parasitic voids have already formed therein, in general there is no longer the possibility to supply further material for the filling of these remaining voids or cavities. According to the present invention, however, also a lateral deposition in the lateral direction of the trench will occur resulting from the broadened trench area, which is still open at this time.

This lateral deposition results in a filling of the remaining voids from the front side (three dimensional filling) and clogs the void in the normally broad channel area of the longitudinal side before the somewhat broader channel position also slowly closes in the upward direction, where typically a somewhat larger remaining void is formed, which does not result in a negative effect, since a hermetic seal is obtained on both sides and in the upward direction. As a result of this hermetic sealing, any post-process gas exchange and thus any negative characteristic of the gas passage in laterally formed voids or cavities and filled trenches may be avoided.

The deposition method performed approximately at vacuum results in an approximately isotropic filling of the broadened trench sections and insures that within the parasitic remaining voids or cavities that an approximately good vacuum remains. Since now substantially no gas is located within the hermetically sealed remaining voids, even high temperature processes may subsequently be applied without having to consider the cracking of such remaining voids.

With respect to the shape of the trench and the slope of the sidewalls, this method may not need to meet particular requirements. The solution of the present invention gains particular importance when remaining voids may not be avoided without additional effort during the filling process.

### EXAMPLES

The subject matter of this invention is now described with reference to the following Examples. These Examples are provided for the purpose of illustration only, and the subject matter is not limited to these Examples, but rather encompasses all variations which are evident as a result of the teaching provided herein.

### Example 1

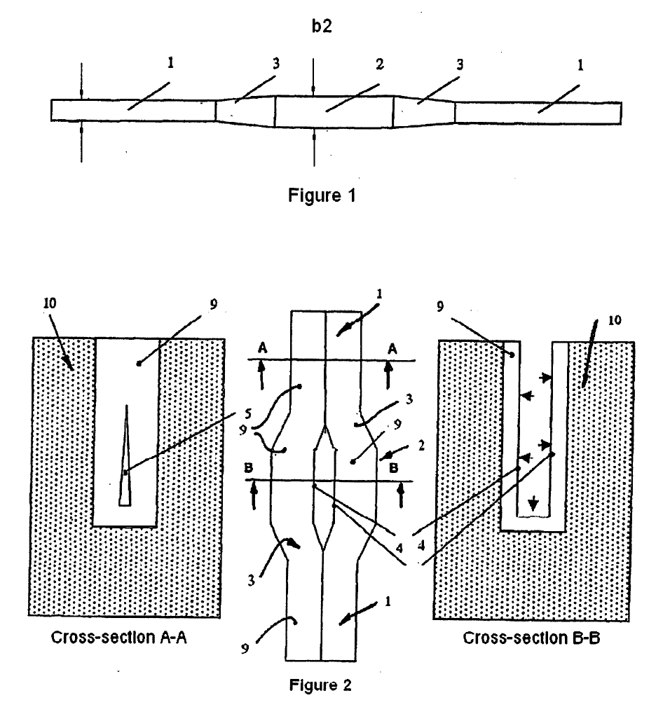

FIG. 1 depicts the trench broadening (2) as a channel broadening (b2), which with both sides (the front ends) are located adjacent to the trench region (1) (channel) having the normal width as indicated (b1). The transition portion (3) between both trench regions should be of conical form.

FIG. 2 represents a schematic diagram of a layer deposition on both sidewalls (4). The deposition (cf. black arrows, cross-sectional plane B-B) occurs identically on the sidewalls (4) within the area of the slight trench broadening (2) after the trench is already closed in the upward direction within the trench region (1), thereby resulting in a small void-channel (5) (cross-sectional plane A-A). The trenches are located within the silicon environment (10).

The trench filling (9) is a fill material, which is deposited. The fill material insures that the trench sections (1) of normal width in FIG. 1 (at the left side and the right side of the conical enlargement of the trench width (b1) towards the slightly broadened trench width (b2) of the section (2) are closed). During the filling within the area of the trenches of normal width the upper trench areas are closed earlier compared to the trench section (2) having the enlarged width (b2).

In the upper trench area fill material is present at this time, wherein a void channel or cavity (5) may form in the longitudinal direction of the trench; that is, the sections (1) of FIG. 1 or FIG. 2. By means of a low pressure material deposition in the broadened trench area (the longitudinal section (2)), the void channels in the longitudinal directions are hermetically sealed. This material deposition is a low pressure material deposition, in which a pressure approximately at vacuum is used.

Thereby, a layer deposition method is used, which results in a substantially isotropic filling of the broadened trench section. Parasitic voids remaining at this position will exhibit substantially no pressure and may rather exhibit an approximately good vacuum due to the low pressure deposition technique.

The sealing is performed on the basis of a three-dimensional filling process occurring in every direction of the trench along its total longitudinal direction, to which belong the narrow sections (1), the conically tapered sections (3) and the slightly broadened trench section (2) having the enlarged width (b2). There may be a plurality of these sections arranged to form a corresponding sequence of which in FIG. 1 merely one broadening is shown that has adjacent to it conical sections (3) and narrower channel sections (1).

At least one position (2) of the plurality of slightly broadened trench sections remains open for a prolonged time period during the layer deposition for the filling compared to the sections (1) having the normal width (b1). From the broadened trench region (2), which is still open in the upward direction at the time of closing the narrower sections (1), there may now occur a lateral deposition in the lateral direction of the trench progression. This lateral deposition results in a filling of the remaining voids from the front side as a three-dimensional filling and also clogs the parasitic void in the channel region (1) having the normal width starting from the longitudinal side. Only at a later stage the broader channel section also slowly closes in the upward direction, thereby forming a somewhat larger void, which is indicated in cross-sectional plane B-B as the inner open area and which is described in more detail in the subsequent figures. This section is not critical, since a hermetic sealing is formed at both sides and in the upward direction.

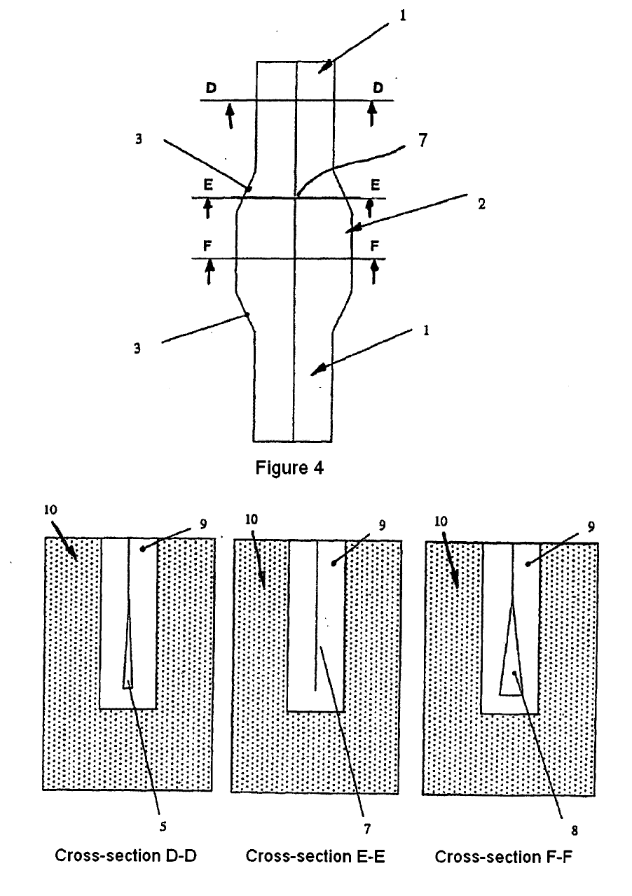

A subsequent gas exchange is avoided. There remains substantially no gas under pressure within the voids so that subsequent processes may be performed with an arbitrary temperature without a risk of cracking of closed channels owing to overpressure forming in the voids (5) or within the larger voids (8) that will be described with reference to FIG. 4, cross-sectional plane F-F.

Contrary to well known techniques trying to avoid voids, the method explained with reference to FIG. 2, which is discussed in even more detail on the basis of the subsequent figures, may tolerate such voids, but nevertheless, avoids any difficulties that may result during the further processing. The isolation trenches or, in short, “trenches,” are filled by means of a deposition technique and are hermetically sealed. They are used for the dielectric insulation on the wafer.

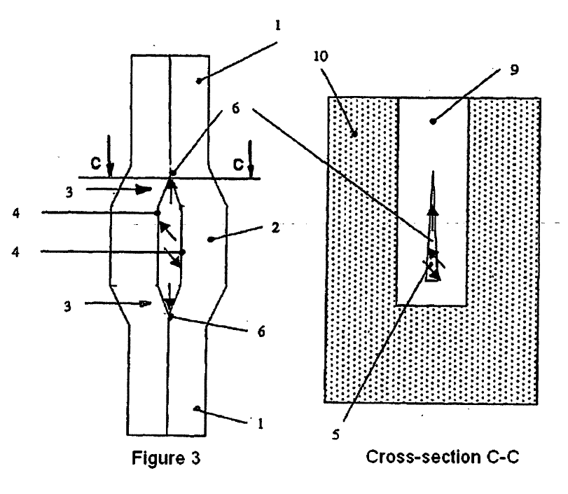

FIG. 3 and cross-sectional plane C-C schematically show a slight trench broadening (2) within a trench progression (1), wherein the trench regions (1) having the normal width (b1) are already closed in the upward direction. In this stage, merely the sidewalls (4) within the trench broadening (2) are coated and also the lateral filling of the parasitic remaining voids at the location of the lateral filling (6) occurs in accordance with the present invention.

Selecting the parameters of the deposition and of the trench arrangement is performed such that possibly remaining lateral voids are completely sealed prior to the closing, in the upward direction, of the trench section having the slight broadening so that a further filling may not be allowed to occur. The layer deposition in FIG. 3 and cross-sectional plane C-C occurs only in the broadened channel section (2), that is, in its region, wherein the lateral filling of the residual remaining voids is emphasized.

FIG. 4, as well as cross-sectional planes D-D, E-E, and F-F, schematically illustrate the results of the completed trench filling. Cross-sectional plane D-D illustrates the smaller remaining void (5) in the normal trench region (1). Cross-sectional plane E-E illustrates the hermetical seal (7) in the area of the conical intermediate or transition portion (3). Cross-sectional plane F-F illustrates the somewhat larger remaining void (8) in the area of the slight trench broadening (2), which is also covered by fill material (9).

FIG. 4 represents a plan view of the trench region to be filled in the sections (1), (2) and again (1). The corresponding components of FIG. 1 may also be applied here without changes.

The slight trench broadening according to the width (b2) (i.e., b2-b1) and the conical transition portion (3) having walls that are oblique with respect to the middle plane are evident from the Figures. There are two transition portions (3) per each slightly broadened trench section (2) for the total trench (1, 2, 1). It is also denoted as a channel.

In the sectional illustration, cross-sectional plane D-D is provided in the area of the narrower trench section (1). A smaller remaining void (5) is indicated, which is on its upper side already closed by fill material (9). A further cross-sectional plane E-E, which is located more downwardly in FIG. 4, illustrates a hermetical seal at the sealing position (7), which is also referred to as a “sealing point.”

A sealed void or inner channel (5) may no longer be seen. The hermetical sealing (7) is performed at a position of the lateral filling (6). The hermetical sealing (7) is located in the area of the conical section (3).

The lateral filling (6) is located closer to the narrower section (1), whereas closer to the broadened section (2) or within the broadened section (2) is located a somewhat enlarged remaining void (8) that is also closed by fill material (9), the upper portion of which, however, has been closed during a later stage of the method compared to the closing process (9) as shown in cross-sectional plane D-D of FIG. 4. The silicon environment of the wafer (10) is denoted similarly as in all other examples.

The broadened trench positions (2) in the form of “sealing positions” of the channel in the vicinity of the bond surfaces of two semiconductor wafers are positioned more densely during the bonding of these wafers than along the other portions of the isolation trenches (not shown in the Figures).

The application of the method also results in the illustrated trench structures according to the previously described method but in the form of a device on or with a wafer comprising isolation trenches, which are hermetically sealed and are used for the dielectric insulation. The process of filling of the trenches was accomplished by a deposition technique as is described.

1. A method for hermetically sealing of dielectrically insulating isolation trenches by filling with a deposition method, wherein the trenches are slightly broadened at specific positions and a low pressure deposition technique is used such that void channels forming in the area of the trenches having normal width by closing the upper trench portions with a fill material are hermetically sealed in the longitudinal direction of the trench by means of low pressure material deposition from the broadened trench portion along the length direction of the trench.

2. The method of claim 1, wherein the broadened trench portions in the vicinity of the bond surfaces of the two semiconductor wafers during the bonding of the two wafers are provided more densely than along the other parts of the isolation trenches.

3. The method of claim 1, wherein the broadened trench portions are provided in regular intervals.

4. An assembly manufactured or manufacturable according to claim 1.

5. A method for hermetically sealing dielectrically insulating isolation trenches by filling with a deposition technique,
(i) wherein the isolation trenches are slightly broadened at least at one specific position;
(ii) a low pressure deposition technique is used to hermetically seal a void in a longitudinal direction of the isolation trench by means of a low pressure material deposition starting from the broadened trench portion along the length direction of the trench, wherein said void is formed in the area of the isolation trenches having the normal width due to the closure of upper trench portions with fill material.

6. The method of claim 5, wherein the broadened trench portions are provided in the vicinity of the bonding surfaces of two semiconductor wafers more densely than along the other sections of the isolation trenches during bonding of the wafers.

7. The method of claim 5, wherein a plurality of broadened trench portions are provided in regular intervals for forming sealing positions along a channel.

8. The method of claim 5, wherein the slightly broadened isolation trenches are broadened at least at one position according to a width that is not greater than the width of the trench at the non-broadened position.

9. The method of claim 5, wherein the broadening is provided by conical sections.

10. The method of claim 5, wherein the low pressure technique is performed substantially at vacuum conditions.

11. The method of claim 5, wherein the broadening is provided at least at a short piece compared to the total length of the channel.

12. The method of claim 5, wherein the selection of parameters of the deposition process and of a trench configuration is performed such that possibly remaining lateral voids are completely sealed before the trench section having the slight broadening closes in the upwards direction so that a further filling cannot take place.

13. A device comprising a wafer having formed therein isolation trenches, said wafer including hermetically sealed dielectrically insulating isolation trenches formed by filling with a deposition method,
(i) wherein the isolation trenches are slightly broadened at least at one specific position;
(ii) wherein void channels are hermetically sealed in the longitudinal direction of the trench by a low pressure material deposition from the broadened trench portion in the longitudinal direction of the trench filled by means of a low pressure deposition technique, said void channels being formed during the filling in the area of the trenches having the normal width by closing the upper trench portions with fill material.
